(19) United States
(12) Patent Application Publication
(10) Pub. No.: US 2026/0371532 A1
(43) Pub. Date: Nov. 19, 2026

(54) BUSBAR ASSEMBLY, COOLING MODULE AND SERVER SYSTEM

(71) Applicant: Wiwynn Corporation, New Taipei City (TW)

(72) Inventors: Hao-Jhan Hong, New Taipei City (TW); CHIA-HSING HSIEH, New Taipei City (TW)

(21) Appl. No.: 19/568,983

(22) Filed: Mar. 17, 2026

Related U.S. Application Data
(60) Provisional application No. 63/805,976, filed on May 14, 2025.

(30) Foreign Application Priority Data
Jan. 7, 2026 (TW) 115100577

(51) Int. Cl. H05K 7/20; H02B 1/21; H02B 1/56; H05K 7/14

(52) U.S. Cl. CPC H05K 7/20781; H02B 1/21; H02B 1/56; H05K 7/1492; H05K 7/20272

(57) ABSTRACT

A busbar assembly includes a busbar and a heat exchanger. The busbar is configured to supply power to at least one server in a server rack, and the busbar comprises at least one channel structure. The heat exchanger is in fluid communication with the channel structure to form a secondary cooling loop. The secondary cooling loop is independent of a main cooling loop in the server rack that cools the server.

### CROSS-REFERENCE TO RELATED APPLICATIONS

This non-provisional application claims priority under 35 U.S.C. § 119(a) on Provisional Application No(s). 63/805,976 filed in U.S.A. on May 14th, 2025, and Patent Application No(s). 115100577 filed in Taiwan, R.O.C. on Jan. 7th, 2026, the entire contents of which are hereby incorporated by reference.

### TECHNICAL FIELD

The disclosure relates to a busbar assembly, a cooling module and a server system.

### BACKGROUND

As the overall power of a server rack increases, air-cooling methods are no longer sufficient to dissipate heat from the servers in the rack. Therefore, most server racks currently use liquid-cooling systems for heat dissipation. In configurations that entirely rely on liquid cooling, there is no fan to drive airflow through the busbar, making it difficult for the busbar to release heat. Consequently, a busbar that can be cooled by a liquid-cooling method has been developed, which receives electrically conductive coolant in a liquid-cooling loop formed by the liquid-cooling system and the server.

However, if the coolant leaks while flowing through the busbar, it may cause a short circuit in the busbar, which may damage the server. In view of this, how to address the aforementioned issue is one of the topics in this field.

### SUMMARY

The disclosure provides a busbar assembly, a cooling module and a server system which are capable of preventing a short circuit in the busbar caused by the leaking coolant.

One embodiment of the disclosure provides a busbar assembly. The busbar assembly includes a busbar and a heat exchanger. The busbar is configured to supply power to at least one server in a server rack, and the busbar comprises at least one channel structure. The heat exchanger is in fluid communication with the channel structure to form a secondary cooling loop. The secondary cooling loop is independent of a main cooling loop in the server rack that cools the server.

Another embodiment of the disclosure provides a cooling module. The cooling module includes a busbar assembly, a cold-liquid manifold and a hot-liquid manifold. The busbar assembly includes a busbar and a heat exchanger. The busbar is configured to supply power to at least one server in a server rack, and the busbar comprises at least one channel structure. The heat exchanger is in fluid communication with the channel structure to form a secondary cooling loop. The cold-liquid manifold is configured to deliver a coolant to the server in the server rack. The hot-liquid manifold is configured to receive the coolant from the server in the server rack. The cold-liquid manifold, the hot-liquid manifold and the server together form a main cooling loop, and the main cooling loop is independent of the secondary cooling loop.

Still another embodiment of the disclosure provides a server system. The server system includes a server rack and a cooling module. The server rack includes a rack and at least one server accommodated in the rack. The cooling module includes a busbar assembly, a cold-liquid manifold and a hot-liquid manifold. The busbar assembly includes a busbar and a heat exchanger. The busbar is electrically connected to the server to supply power to the server, and the busbar comprises at least one channel structure. The heat exchanger is in fluid communication with the channel structure to form a secondary cooling loop. The cold-liquid manifold is connected to the server to deliver a coolant to the server. The hot-liquid manifold is connected to the server to receive the coolant from the server in the server rack. The cold-liquid manifold, the hot-liquid manifold and the server together form a main cooling loop, and the main cooling loop is independent of the secondary cooling loop.

According to the busbar assembly, the cooling module and the server system as discussed in the above embodiments, the secondary cooling loop is formed by the busbar and the heat exchanger, and the secondary cooling loop is independent of the main cooling loop formed by the cold-liquid manifold, the hot-liquid manifold and the server. In such a configuration, the secondary cooling loop and the main cooling loop can use different coolants (e.g., the secondary cooling loop uses an electrically insulating liquid, whereas the main cooling loop uses an electrically conductive liquid). Accordingly, even if the coolant flowing in the busbar leaks, a short circuit of the busbar is prevented, thereby ensuring normal operation of the server.

### BRIEF DESCRIPTION OF THE DRAWINGS

The present disclosure will become better understood from the detailed description given herein below and the accompanying drawings which are given by way of illustration only and thus are not intending to limit the present disclosure and wherein:

FIG. 1 is a rear view of a server system according to some embodiments of the disclosure;

FIG. 2 is a block diagram of a cooling module according to some embodiments of the disclosure;

FIG. 3 is a perspective view of a busbar according to some embodiments of the disclosure;

FIG. 4 is a cross-sectional view of a busbar according to some embodiments of the disclosure;

FIGS. 5 and 6 are different side views of a busbar according to some embodiments of the disclosure;

FIG. 7 is a perspective view of a busbar according to some embodiments of the disclosure;

FIGS. 8 and 9 are different side views of a busbar according to some embodiments of the disclosure;

FIG. 10 is a block diagram of a cooling module according to some embodiments of the disclosure;

FIG. 11 is a block diagram of a cooling module according to some embodiments of the disclosure; and

FIG. 12 is a perspective view of a server system according to some embodiments of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the present disclosure, such as technical and scientific terms, have its own meanings and can be comprehended by those skilled in the art, unless the terms are additionally defined in the present disclosure. That is, the terms used in the following paragraphs should be read on the meaning commonly used in the related fields and will not be overly explained, unless the terms have a specific meaning in the present disclosure.

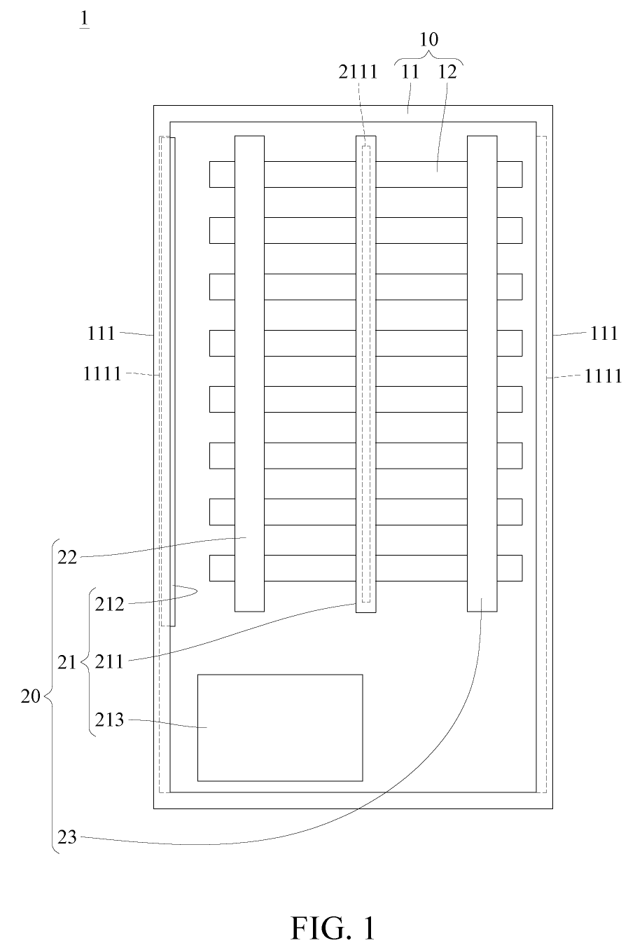

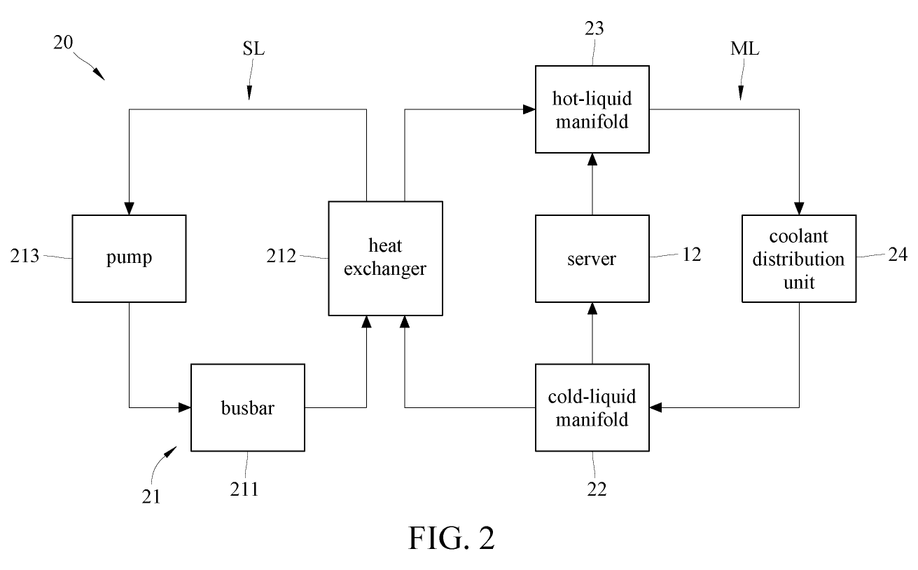

Referring to FIGS. 1 and 2, FIG. 1 is a rear view of a server system 1 according to some embodiments of the disclosure, and FIG. 2 is a block diagram of a cooling module 20 according to some embodiments of the disclosure. In FIG. 2, the connection between two components indicated by an arrow represents that the two components are in fluid communication via a pipe and indicates the flow direction of the coolant in the pipe. The structural features shown in FIGS. 1 and 2 may be applied to other embodiments of the disclosure.

The server system 1 includes a server rack 10 and a cooling module 20. The server rack 10 includes a rack 11 and at least one server 12 accommodated in the rack 11. The cooling module 20 includes a busbar assembly 21, a cold-liquid manifold 22 and a hot-liquid manifold 23. The busbar assembly 21 includes a busbar 211 and a heat exchanger 212. The busbar 211 is electrically connected to the server 12 to supply power thereto and includes at least one channel structure 2111. The heat exchanger 212 is in fluid communication with the channel structure 2111 to form a secondary cooling loop SL for conveying a first coolant (not shown). The cold-liquid manifold 22 is connected to the server 12 and is configured to deliver a second coolant (not shown) to the server 12. The hot-liquid manifold 23 is connected to the server 12 and is configured to receive the second coolant from the server 12 in the server rack 10. The cold-liquid manifold 22, the hot-liquid manifold 23 and the server 12 together form a main cooling loop ML, and the main cooling loop ML is independent of the secondary cooling loop SL. That is, the main cooling loop ML and the secondary cooling loop SL do not share any flow channels or pipes, ensuring that the second coolant in the main cooling loop ML does not come into contact with the first coolant in the secondary cooling loop SL.

In some embodiments, the number of server 12 may be multiple. The servers 12 may, for example, be stacked in layers from the top to the bottom of the rack 11 and placed horizontally in the rack 11, but the disclosure is not limited thereto. In other embodiments, the servers may, for example, be placed upright from the left side to the right side of the rack.

In some embodiments, the heat exchanger 212 is disposed at a rear side of the rack 11. For example, the heat exchanger 212 may be disposed at a rear side of one of sidewalls 111 of the rack 11. In some embodiments, the rack 11 includes two sidewalls 111 located opposite to each other, each sidewall 111 is provided with an elongated recess 1111. The heat exchanger 212 is in an elongated shape and disposed in the elongated recess 1111 of one of the two sidewalls 111. The elongated recesses 1111 of the two sidewalls 111 are also configured to accommodate physical cables, such as network cables. The heat exchanger 212 is in the elongated shape and accommodated in the elongated recess 1111 of one of the sidewalls 111, and both the upper and lower ends of the heat exchanger 212 may be provided with an inlet and an outlet, which effectively reduce the space occupied by the heat exchanger 212 in the rack 11. Compared to conventional liquid-to-liquid heat exchangers, this configuration further frees up space for components such as liquid fittings and pipes. The other elongated recess 1111, which does not accommodate the heat exchanger 212, may still be used to accommodate physical cables, such as network cables.

In some embodiments, the busbar assembly 21 may further include a pump 213. The pump 213, the busbar 211, and the heat exchanger 212 together form the secondary cooling loop SL. In some embodiments, the busbar 211 is located downstream of the pump 213 and upstream of the heat exchanger 212. The pump 213 is configured to drive the first coolant such that the first coolant is conveyed in the secondary cooling loop SL. When the first coolant flows into the busbar 211, the first coolant absorbs heat generated by power transmission of the busbar 211 and increases in temperature, thereby cooling the busbar 211. After leaving the busbar 211, the first coolant enters the heat exchanger 212 and is cooled, where how the first coolant is cooled will be described later. The cooled first coolant then returns to the pump 213.

It should be noted that the upstream and downstream relationships among the pump 213, the busbar 211 and the heat exchanger 212 may be adjusted as required. In other embodiments, the pump may be located downstream of the busbar and upstream of the heat exchanger.

In some embodiments, the cooling module 20 may further include a coolant distribution unit 24. The coolant distribution unit 24, the cold-liquid manifold 22, the hot-liquid manifold 23 and the server 12 together form the main cooling loop ML.

In some embodiments, the coolant distribution unit 24 may be disposed in the rack 11 together with the server 12, thereby forming an in-rack coolant distribution unit (i.e., In-rack CDU). Alternatively, the coolant distribution unit 24 may be disposed in another rack (not shown) located adjacent to the server rack 10, thereby forming an in-row coolant distribution unit (i.e., In-row CDU).

In some embodiments, the coolant distribution unit 24, for example, includes a pump and a radiator (both not shown). The pump of the coolant distribution unit 24 is configured to deliver the second coolant to the cold-liquid manifold 22. The cold-liquid manifold 22 is configured to deliver the second coolant to the server 12, such that the second coolant absorbs heat generated by heat sources in the server 12 and is thereby heated. The hot-liquid manifold 23 is configured to receive the heated second coolant from the server 12 and to deliver the heated second coolant to the coolant distribution unit 24, where the second coolant is cooled by the radiator of the coolant distribution unit 24. The second coolant in the radiator may be cooled by air cooling or liquid cooling. For example, heat of the second coolant in the radiator may be removed by airflow generated by a fan. Alternatively, the radiator may be thermally coupled to another cooling loop (e.g., a facility water loop), such that heat of the second coolant in the radiator is transferred to a coolant (e.g., facility water) in this cooling loop, thereby cooling the second coolant.

In some embodiments, the cold-liquid manifold 22, the hot-liquid manifold 23 and the heat exchanger 212 are in fluid communication with each other, where the heat exchanger 212 is located downstream of the cold-liquid manifold 22 and upstream of the hot-liquid manifold 23. Accordingly, a portion of the low-temperature second coolant in the main cooling loop ML may flow into the heat exchanger 212, such that high-temperature first coolant in the secondary cooling loop SL entering the heat exchanger 212 exchanges heat with the low-temperature second coolant. As a result, the first coolant leaving the heat exchanger 212 returns to the pump 213 at a lower temperature, and the second coolant leaving the heat exchanger 212 returns to the hot-liquid manifold 23 (i.e., the main cooling loop ML) at a higher temperature.

In some embodiments, the first coolant is an electrically insulating liquid, and the first coolant is different from the second coolant. For example, the second coolant may be an electrically conductive liquid, but the disclosure is not limited thereto. In other embodiments, the first coolant and the second coolant may be different types of electrically insulating liquids.

In the above embodiments, the secondary cooling loop SL is formed by the busbar 211 and the heat exchanger 212, and the secondary cooling loop SL is independent of the main cooling loop ML formed by the cold-liquid manifold 22, the hot-liquid manifold 23 and the server 12. In such a configuration, the secondary cooling loop SL and the main cooling loop ML can use different coolants (e.g., the secondary cooling loop SL uses an electrically insulating liquid, whereas the main cooling loop ML uses an electrically conductive liquid). Accordingly, even if the coolant flowing in the busbar 211 leaks, a short circuit of the busbar 211 is prevented, thereby ensuring normal operation of the server 12.

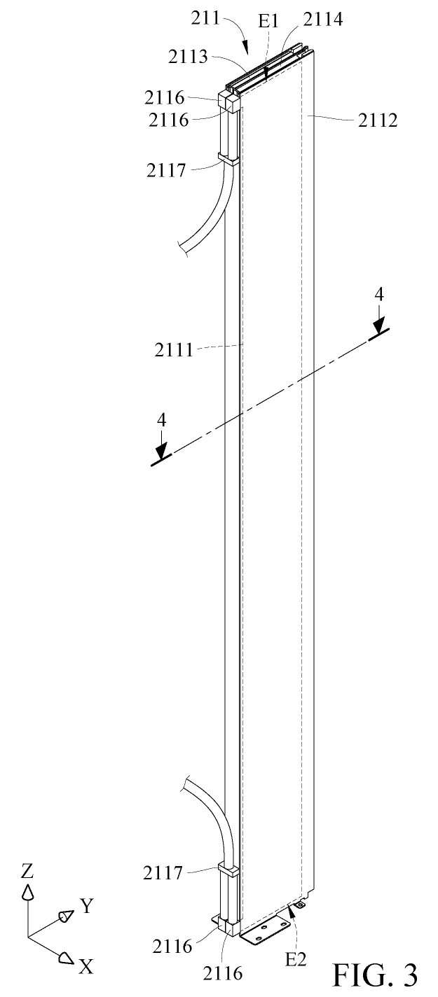

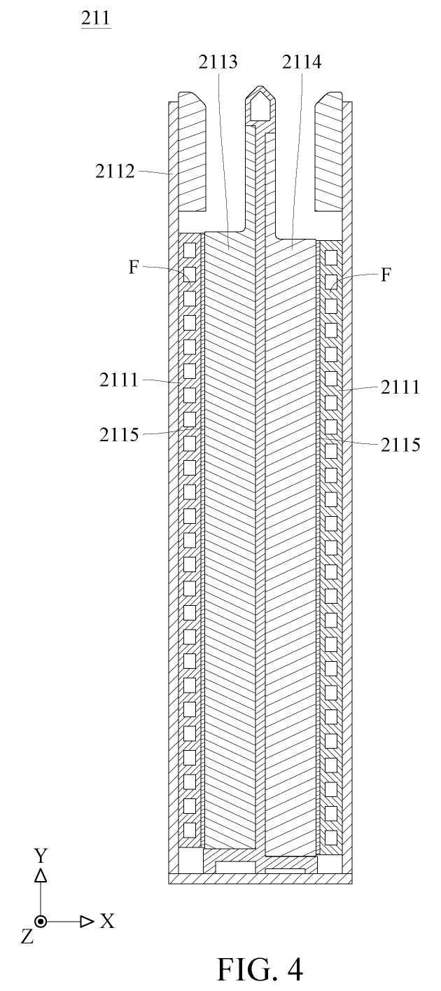

Then, referring to FIGS. 3 and 4, FIG. 3 is a perspective view of the busbar 211 according to some embodiments of the disclosure, and FIG. 4 is a cross-sectional view of the busbar 211 according to some embodiments of the disclosure, where FIG. 4 is a cross-sectional view taken along a line 4-4 in FIG. 3. The structural features shown in FIGS. 3 and 4 may be applied to other embodiments of the disclosure.

In some embodiments, the busbar 211 may include a housing 2112, a positive electrode 2113 and a negative electrode 2114. The positive electrode 2113, the negative electrode 2114 and the channel structure 2111 are disposed in the housing 2112, and the channel structure 2111 is thermally coupled to the positive electrode 2113 and the negative electrode 2114.

In some embodiments, the busbar 211 may further include at least one electrically insulating thermally conductive material 2115. The channel structure 2111 is thermally coupled to and electrically insulated from the positive electrode 2113 and the negative electrode 2114 via the electrically insulating thermally conductive material 2115.

In some embodiments, each channel structure 2111 may include a plurality of fin structures F. For example, the fin structures F are arranged in parallel and extend from one end of the channel structure 2111 to the other end. It should be noted that the fin structures F are optional, and may be omitted in other embodiments.

In some embodiments, the busbar 211 further includes two fittings 2116, and the two fittings 2116 are respectively connected to two opposite ends of the channel structure 2111.

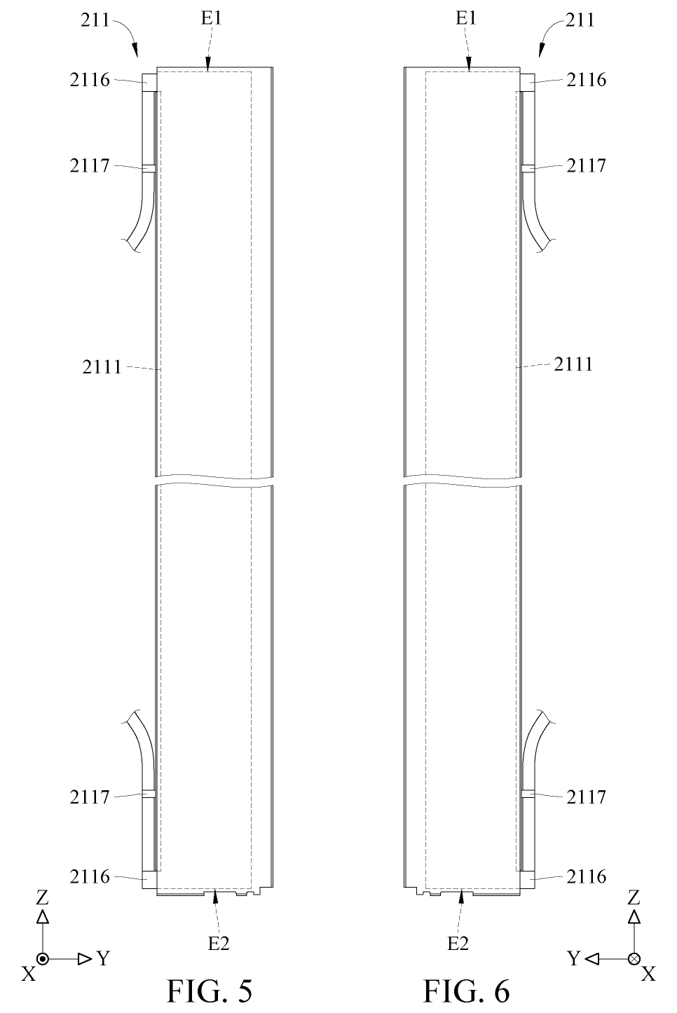

Referring to FIGS. 3 - 6, FIGS. 5 and 6 are different side views of the busbar 211 according to some embodiments of the disclosure. The structural features shown in FIGS. 5 and 6 may be applied to other embodiments of the disclosure.

In some embodiments, the busbar 211 may include two channel structures 2111, two electrically insulating thermally conductive materials 2115, four fittings 2116 and two three-way fittings 2117. The two channel structures 2111 are respectively thermally coupled to the positive electrode 2113 and the negative electrode 2114 via the two electrically insulating thermally conductive materials 2115.

Two of the fittings 2116 are respectively connected to a first end E1 (e.g., top end) and a second end E2 (e.g., bottom end) of one of the channel structures 2111 located opposite to each other, and the other two fittings 2116 are respectively connected to a first end E1 (e.g., top end) and a second end E2 (e.g., bottom end) of the other channel structure 2111 located opposite to each other. As a result, the two fittings 2116 connected to the first ends E1 of the two channel structures 2111 are arranged side by side, and the two fittings 2116 connected to the second ends E2 of the two channel structures 2111 are arranged side by side. One of the three-way fittings 2117 is connected to the two side-by-side fittings 2116 and is connected to one of the pump 213 and the heat exchanger 212 via a pipe. The other three-way fitting 2117 is connected to the other two side-by-side fittings 2116 and is connected to the other of the pump 213 and the heat exchanger 212 via a pipe.

It should be noted that the busbar 211 is not limited to including two channel structures 2111. In other embodiments, the busbar may include a single channel structure. In such a configuration, the three-way fittings may be omitted, the busbar may include only two fittings 2116 respectively connected to two opposite ends of the single channel structure, and two opposite sides of the single channel structure may be thermally coupled to the positive electrode and the negative electrode via two electrically insulating thermally conductive materials. In the embodiment with a single channel structure, the busbar is not limited to including two electrically insulating thermally conductive materials. In other embodiments, the single channel structure may be thermally coupled to the positive and negative electrodes via a single electrically insulating thermally conductive material.

In the above embodiments, by configuring the busbar 211 to include the channel structures 2111, by thermally coupling the channel structures 2111 to the positive electrode 2113 and the negative electrode 2114, and by providing fin structures F in the channel structures 2111, the first coolant flowing into the channel structure 2111 can absorb heat generated by the positive electrode 2113 and the negative electrode 2114 during the power delivery to the server 12, thereby achieving the desired cooling performance.

For example, based on simulation results, when the first coolant is an electrically insulating and thermally conductive synthetic oil (POE), the power dissipation of the busbar is 3390 W, the fin structures F have a thickness of 2 mm and a spacing of 2 mm, the first coolant flow rate is 7 LPM, and the temperature of the first coolant at the inlet of the channel structure 2111 is 30 °C, the temperature of the first coolant at the outlet of the channel structure 2111 can reach 51° C, the maximum temperature of the busbar can reach 55.3° C (i.e., a temperature difference of 25.3° C relative to the inlet temperature of the first coolant), and the pressure drop between the inlet and outlet of the channel structure 2111 is 15.8 psi. Accordingly, the first coolant can effectively carry away heat generated by the positive electrode 2113 and the negative electrode 2114 during power delivery to the server 12, thereby achieving the desired cooling performance.

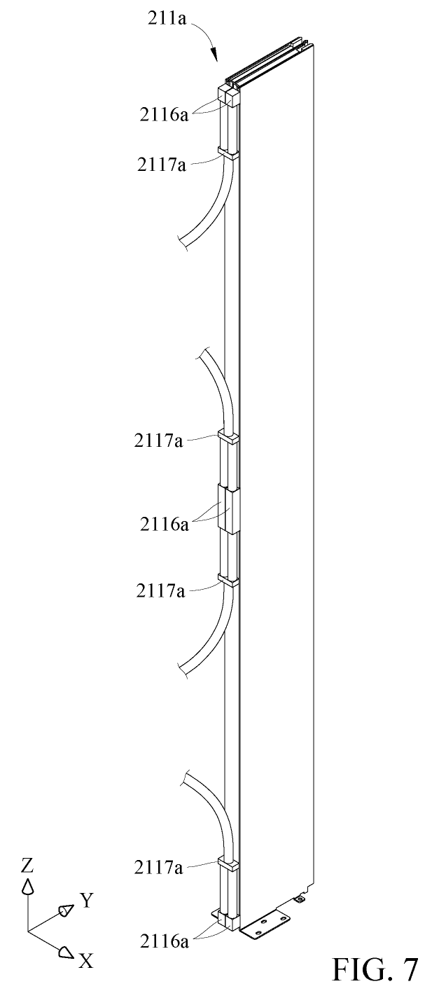

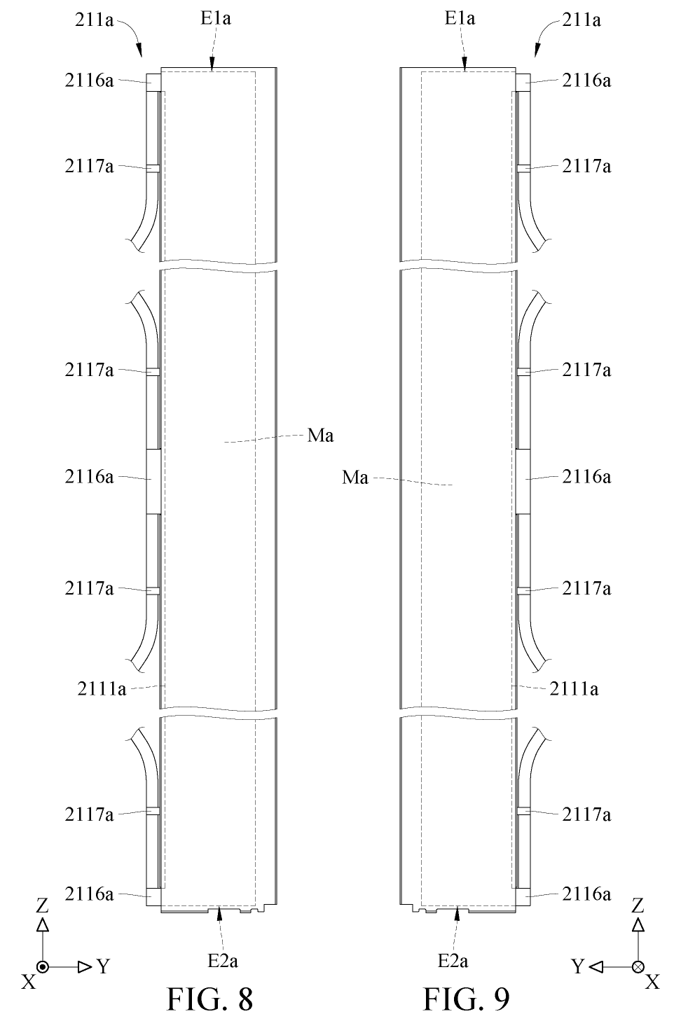

Then, referring to FIGS. 7 - 9, FIG. 7 is a perspective view of a busbar 211a according to some embodiments of the disclosure, and FIGS. 8 and 9 are different side views of the busbar 211a according to some embodiments of the disclosure. The structural features shown in FIGS. 7- 9 may be applied to other embodiments of the disclosure.

The busbar 211a of the embodiments shown in FIGS. 7 - 9 is similar to the busbar 211 of the embodiment shown in FIG. 3. The following descriptions focus on the differences between the them, and the same parts are not described again.

In the busbar 211a of the embodiments shown in FIGS. 7- 9, the busbar 211a includes six fittings 2116a and four three-way fittings 2117a. Three of the fittings 2116a are respectively connected to opposite first and second ends E1a (e.g., top end) and E2a (e.g., bottom end) and to a middle portion Ma (located longitudinally between E1a and E2a) of one of the channel structures 2111a, and the other three fittings 2116a are respectively connected to opposite first and second ends E1a (e.g., top end) and E2a (e.g., bottom end) and to a middle portion Ma (located longitudinally between E1a and E2a) of the other channel structure 2111a. One of the three-way fittings 2117a is connected to the two fittings 2116a connected to the first ends E1a of the two channel structures 2111a, another three-way fitting 2117a is connected to the two fittings 2116a connected to the second ends E2a of the two channel structures 2111a, and the other two three-way fittings 2117a are connected to the two fittings 2116a connected to the middle portions Ma of the two channel structures 2111a.

In some embodiments, the two three-way fittings 2117a connected to the fittings 2116a at the first ends E1a and the second ends E2a of the two channel structures 2111a may serve as inlet fittings, while the two three-way fittings 2117a located at the middle portions Ma may serve as outlet fittings. That is, the low-temperature first coolant may flow into the top and bottom ends of the two channel structures 2111a, and the first coolant, which absorbs heat and increases in temperature, may flow out from the middle portions Ma of the two channel structures 2111a. This configuration is applicable to a case where the heat-concentrated portions of the busbar 211a are located at the top and bottom of the busbar 211a.

In some embodiments, the two three-way fittings 2117a connected to the fittings 2116a at the first ends E1a and the second ends E2a of the two channel structures 2111a may serve as outlet fittings, while the two three-way fittings 2117a located at the middle portions Ma may serve as inlet fittings. That is, the low-temperature first coolant may flow into the middle portions Ma of the two channel structures 2111a, and the first coolant, which absorbs heat and increases in temperature, may flow out from the top and bottom ends of the two channel structures 2111a. This configuration is applicable to a case where the heat-concentrated portions of the busbar 211a are located near the middle portions Ma.

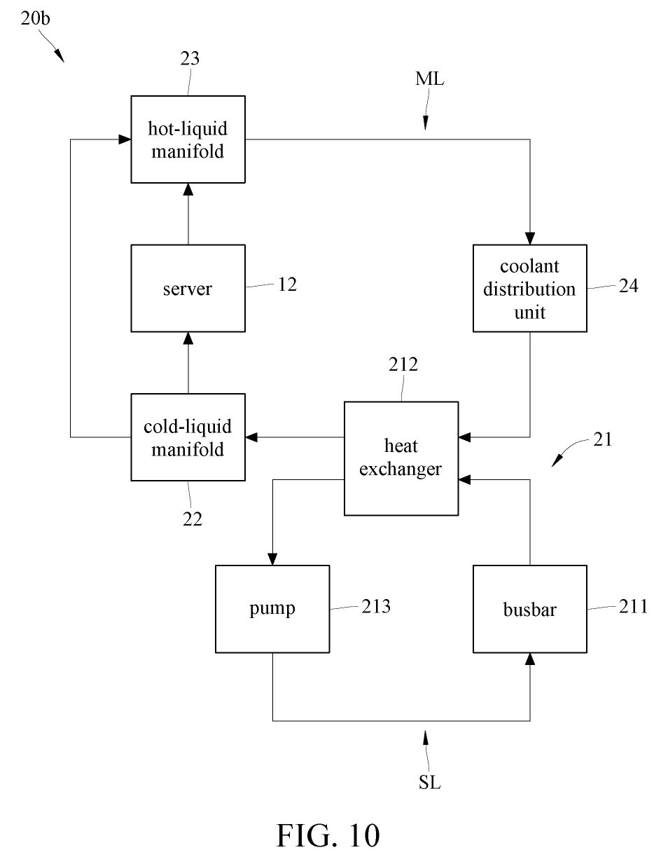

Then, referring to FIG. 10, FIG. 10 is a block diagram of a cooling module 20b according to some embodiments of the disclosure. The structural features shown in FIG. 10 may be applied to other embodiments of the disclosure.

The cooling module 20b of the embodiment shown in FIG. 10 is similar to the cooling module 20 in the embodiment shown in FIG. 2. The following mainly describes the differences between them, and the same parts are not described again.

In the cooling module 20b of the embodiment shown in FIG. 10, the heat exchanger 212 is in fluid communication with the cold-liquid manifold 22 and the coolant distribution unit 24, and the heat exchanger 212 is located upstream of the cold-liquid manifold 22 and downstream of the coolant distribution unit 24.

It should be noted that the upstream and downstream relationship between the busbar 211 and the pump 213 in FIG. 10 can be interchanged as required.

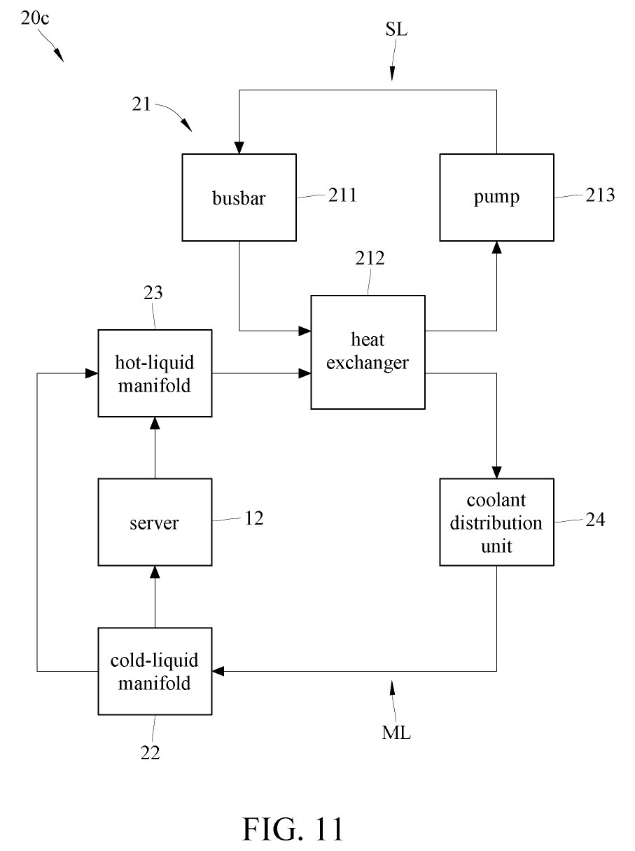

Then, referring to FIG. 11, FIG. 11 is a block diagram of a cooling module 20c according to some embodiments of the disclosure. The structural features shown in FIG. 11 may be applied to other embodiments of the disclosure.

The cooling module 20c of the embodiment shown in FIG. 11 is similar to the cooling module 20 in the embodiment shown in FIG. 2. The following mainly describes the differences between them, and the same parts are not described again.

In the cooling module 20c of the embodiment shown in FIG. 11, the heat exchanger 212 is in fluid communication with the hot-liquid manifold 23 and the coolant distribution unit 24, and the heat exchanger 212 is located downstream of the hot-liquid manifold 23 and upstream of the coolant distribution unit 24.

It should be noted that the upstream and downstream relationship between the busbar 211 and the pump 213 in FIG. 11 can be interchanged as required.

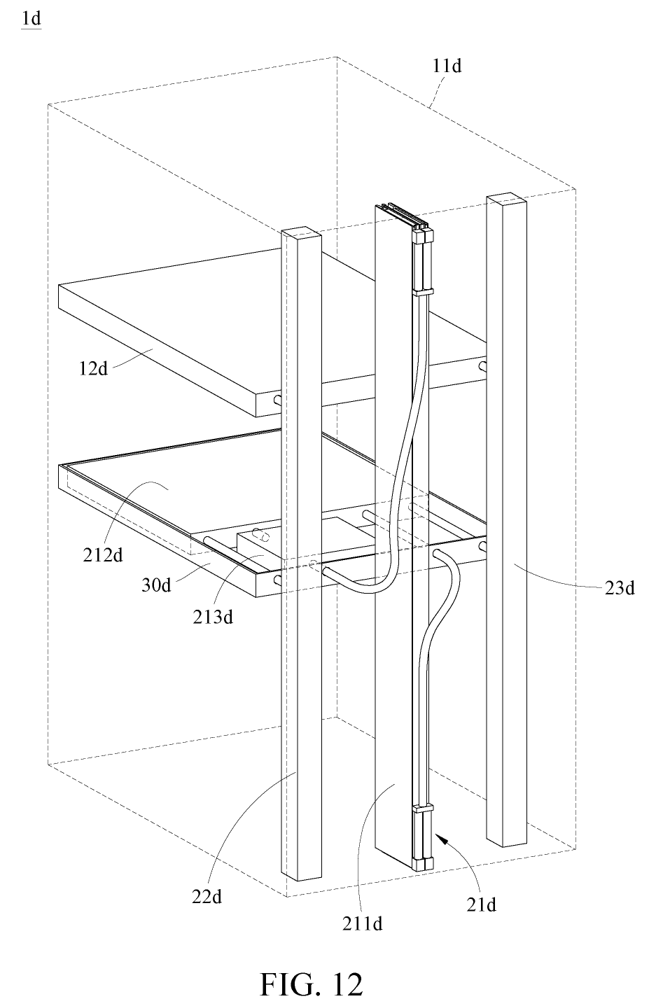

Then, referring to FIG. 12, FIG. 12 is a perspective view of a server system 1d according to some embodiments of the disclosure. The structural features shown in FIG. 12 may be applied to other embodiments of the disclosure.

The server system 1d of the embodiment shown in FIG. 12 is similar to the server system 1 in the embodiment shown in FIG. 1. The following mainly describes the differences between them, and the same parts are not described again.

In this embodiment, the server system 1d may further include a tray 30d. The tray 30d may be movably disposed in a rack 11d and arranged side by side with a server 12d. A pump 213d and a heat exchanger 212d of a busbar assembly 21d are disposed in the tray 30d. The pump 213d and the heat exchanger 212d in the tray 30d form a secondary cooling loop with a busbar 211d. The heat exchanger 212d in the tray 30d is in fluid communication with a cold-liquid manifold 22d and a hot-liquid manifold 23d of the main cooling loop, so that the first coolant in the secondary cooling loop and the second coolant in the main cooling loop can exchange heat in the heat exchanger 212d.

According to the busbar assembly, the cooling module and the server system as discussed in the above embodiments, the secondary cooling loop is formed by the busbar and the heat exchanger, and the secondary cooling loop is independent of the main cooling loop formed by the cold-liquid manifold, the hot-liquid manifold and the server. In such a configuration, the secondary cooling loop and the main cooling loop can use different coolants (e.g., the secondary cooling loop uses an electrically insulating liquid, whereas the main cooling loop uses an electrically conductive liquid). Accordingly, even if the coolant flowing in the busbar leaks, a short circuit of the busbar is prevented, thereby ensuring normal operation of the server.

It will be apparent to those skilled in the art that various modifications and variations can be made to the present disclosure. It is intended that the specification and examples be considered as exemplary embodiments only, with a scope of the disclosure being indicated by the following claims and their equivalents.

What is claimed is:

1. A busbar assembly, comprising:
a busbar, configured to supply power to at least one server in a server rack, wherein the busbar comprises at least one channel structure; and
a heat exchanger, in fluid communication with the at least one channel structure to form a secondary cooling loop, wherein the secondary cooling loop is independent of a main cooling loop in the server rack that cools the at least one server.

2. The busbar assembly according to claim 1, further comprising a pump, wherein the pump, the busbar and the heat exchanger together form the secondary cooling loop.

3. The busbar assembly according to claim 1, wherein the busbar comprises a housing, a positive electrode and a negative electrode, the positive electrode, the negative electrode, and the at least one channel structure are disposed in the housing, the at least one channel structure is thermally coupled to the positive electrode and the negative electrode.

4. The busbar assembly according to claim 3, wherein the at least one channel structure comprises two channel structures, and the two channel structures are respectively thermally coupled to the positive electrode and the negative electrode.

5. The busbar assembly according to claim 3, wherein the busbar further comprises at least one electrically insulating thermally conductive material, the at least one channel structure is thermally coupled to and electrically insulated from the positive electrode and the negative electrode via the at least one electrically insulating thermally conductive material.

6. The busbar assembly according to claim 3, wherein the busbar further comprises two fittings, and the two fittings are respectively connected to two opposite ends of the at least one channel structure.

7. The busbar assembly according to claim 3, wherein the busbar further comprises three fittings, two of the three fittings are respectively connected to two opposite ends of the at least one channel structure, and the remaining one of the three fittings is connected to a middle portion of the at least one channel structure.

8. The busbar assembly according to claim 1, wherein the secondary cooling loop is configured to convey a first coolant, the main cooling loop is configured to convey a second coolant, and the first coolant is an electrically insulating liquid and is different from the second coolant.

9. A cooling module, comprising:
a busbar assembly, comprising:
a busbar, configured to supply power to at least one server in a server rack, wherein the busbar comprises at least one channel structure; and
a heat exchanger, in fluid communication with the at least one channel structure to form a secondary cooling loop;
a cold-liquid manifold, configured to deliver a coolant to the at least one server in the server rack; and
a hot-liquid manifold, configured to receive the coolant from the at least one server in the server rack, wherein the cold-liquid manifold, the hot-liquid manifold and the at least one server together form a main cooling loop, and the main cooling loop is independent of the secondary cooling loop.

10. The cooling module according to claim 9, wherein the cold-liquid manifold, the hot-liquid manifold and the heat exchanger are in fluid communication with each other.

11. The cooling module according to claim 9, wherein the heat exchanger is in fluid communication with the cold-liquid manifold and is located upstream of the cold-liquid manifold.

12. The cooling module according to claim 9, wherein the heat exchanger is in fluid communication with the hot-liquid manifold and is located downstream of the hot-liquid manifold.

13. The cooling module according to claim 9, wherein the busbar assembly further comprises a pump, and the pump, the busbar and the heat exchanger together form the secondary cooling loop.

14. A server system, comprising:
a server rack, comprising a rack and at least one server accommodated in the rack; and
a cooling module, comprising:
a busbar assembly, comprising:
a busbar, electrically connected to the at least one server to supply power to the at least one server, wherein the busbar comprises at least one channel structure; and
a heat exchanger, in fluid communication with the at least one channel structure to form a secondary cooling loop;
a cold-liquid manifold, connected to the at least one server to deliver a coolant to the at least one server; and
a hot-liquid manifold, connected to the at least one server to receive the coolant from the at least one server in the server rack, wherein the cold-liquid manifold, the hot-liquid manifold and the at least one server together form a main cooling loop, and the main cooling loop is independent of the secondary cooling loop.

15. The server system according to claim 14, wherein the cold-liquid manifold, the hot-liquid manifold and the heat exchanger are in fluid communication with each other.

16. The server system according to claim 14, wherein the heat exchanger is in fluid communication with the cold-liquid manifold and is located upstream of the cold-liquid manifold.

17. The server system according to claim 14, wherein the heat exchanger is in fluid communication with the hot-liquid manifold and is located downstream of the hot-liquid manifold.

18. The server system according to claim 14, wherein the heat exchanger is disposed on a rear side of the rack.

19. The server system according to claim 14, wherein the busbar assembly further comprises a pump, and the pump, the busbar and the heat exchanger together form the secondary cooling loop.

20. The server system according to claim 19, further comprising a tray, wherein the tray is movably disposed in the server rack and arranged side by side with the at least one server, and the pump and the heat exchanger are disposed on the tray.

21. The server system according to claim 15, wherein the heat exchanger is located downstream of the cold-liquid manifold.

22. The server system according to claim 14, wherein each of two opposite sidewalls of the rack is provided with an elongated recess, and the heat exchanger is in an elongated shape and is disposed in the elongated recess of one of the two sidewalls.
